(19) United States
(12) Patent Application Publication
(10) Pub. No.: US 2014/0084955 A1
(43) Pub. Date: Mar. 27, 2014

(54) FINE PITCH INTERPOSER STRUCTURE

(71) Applicant: CHUNGHWA PRECISION TEST TECH CO., LTD., TAOYUAN COUNTY (TW)

(72) Inventors: YUAN-CHIANG TENG, TAOYUAN COUNTY 326 (TW); KAI-CHIEH HSIEH, TAOYUAN COUNTY 328 (TW); WEN-TSUNG LEE, NEW TAIPEI CITY 241 (TW)

(73) Assignee: CHUNGHWA PRECISION TEST TECH CO., LTD., TAOYUAN COUNTY (TW)

(21) Appl. No.: 13/837,600

(22) Filed: Mar. 15, 2013

(30) Foreign Application Priority Data
Sep. 21, 2012 (TW) 101218286

(51) Int. Cl. G01R 1/04; H05K 1/09

(52) U.S. Cl. CPC G01R 1/0491; H05K 1/09
USPC 324/756.03; 174/262; 174/256

(57) ABSTRACT

A fine pitch interposer structure includes a Multi-core base substrate and a plurality of buildup laminates. A surface of each Multi-core base substrate has a first circuit layer, and a second circuit layer which is electrically connected to the first circuit layer. The buildup laminates are stacked on the surface of the Multi-core base substrate. Each buildup laminate includes a photosensitive dielectric layer, and a plurality of blind vias with a pre-determined interval therebetween which are correspondingly arranged on each of the plurality of vias formed on the photosensitive dielectric layer. The blind vias are electrically connected to the first circuit layer. At least one blind via of one buildup laminate is superimposed on another blind via of another buildup laminate.

### BACKGROUND OF THE INVENTION

1. Field of the Invention

The instant disclosure relates to an interposer structure; in particular, to a fine pitch interposer structure for testing integrated circuits (IC) or packaged IC.

2. Description of Related Art

Refer to FIGS. 1 to 3 as a common vertical wafer testing structure including a printed circuit board 2A which is connected to test equipment, and an interposer 1A which is connected to the printed circuit board 2A. While the interposer 1A is connected to a plurality of wafer test probes 11A to test wafers 4A on a floating platform 3A. The interposer 1A structure can be divided into (1) Multi-layer ceramic (MLC) 1B as shown in FIG. 2, and (2) Multi-layer organic (MLO) 1C as shown in FIG. 3. However, the fabrication process for the two structures significantly varies as MLC requires low temperature co-fired ceramic (LTCC) fabrication process, with the application of green tapes, printing process and high temperature sintering to complete the fabrication. Generally, quantity of layers is high which leads to higher cost, whereas the MLO fabrication only requires processing on the printed circuit board, in which circuits are miniaturized through photolithography. However, laser drilling process is still applied for via formation process which limits the materials and processing capacity.

In terms of MLC interposer, the common design frequently uses a single device under test (DUT) or a pair of DUT (Dual DUT) for testing. When the quantity of I/O testing point increases or a multi DUT testing is required, the complexity of the design gradually increases. With the printing process, the finest width of the traces is approximately 100 microns which limits the density in circuit layouts. In such a case, the quantity of laminate layers must increase in order to disperse denser circuit layouts which may result in forming over 50 laminate layers. In addition, further laser processing for via formation is required for each layer along with the application of silver paste for plugging via and print circuits which leads to relatively high cost and long delivery time.

MLO interposer for testing may use PCB process and materials, however, with fine pitch fabrication, buildup laminate materials are limited. When applying materials containing fiber glass after laser drilling and electroplating, the wick effect tends to render short-circuiting and scrapping. Materials for mass production packaging of flip chip interposer (Ajinomoto Build-up film, ABF) tend to not contain glass fibers. However, with the application of the materials mentioned above, expensive lamination, copperizing equipment and solution for electroplating are not readily affordable by a common sample factory (such as a customized interposer manufacturer).

In flip chip packaging, ball grid array is a common I/O arrangement. Since the fine pitch testing capability greatly depends on the miniaturization of vias, a matrix arrangement is necessary. However, now only do the non-fiber glass materials needs to undergo carbon dioxide (CO₂) or ultraviolent laser drilling, but a Desmear process is necessary thereafter which leads to serious over drilling and rendering larger via diameter than desired. As the limit of the pitch of the finished product is 140 microns, further laser drilling may be applied to miniaturize the diameter of vias without the Desmear process. However, the glass transition temperature (T_{g}) of the material is not high enough (approximately 150° C.) and the thermal expansion coefficient is too large (CTE approximately 250 ppm/° C.) which renders questionable reliability of the post-production assembly.

To address the above issues, the inventor strives via associated experience and research to present the instant disclosure, which can effectively improve the limitation described above.

### SUMMARY OF THE INVENTION

The instant disclosure provides a fine pitch interposer structure including vias (vertical interconnected access) having fine diameters for further improving fine pitch testing capability.

In order to achieve the aforementioned objective, according to embodiments of the instant disclosure, the fine pitch interposer structure includes a Multi-core base substrate which has opposing surfaces. A first circuit layer and a second circuit layer electrically connected to the first circuit layer are disposed on the opposing surfaces. A plurality of buildup laminates is stacked on other laminates in succession on the surface of the Multi-core base substrate. Each buildup laminate includes a photosensitive dielectric layer and a plurality of blind vias. The blind vias are respectively arranged on a plurality of vias formed on the photosensitive dielectric layer, and are electrically connected to the first circuit layer with a pre-determined interval therebetween. Furthermore, the blind vias of at least one buildup laminate superimpose the blind vias of another buildup laminate.

Preferably, a diameter of each of the vias is no more than 62.5 microns.

Preferably, the blind vias are arranged in an array matrix configuration. The distance between the center of a blind via and the center of an adjacent blind via is a pitch, and the pitch is no more than 140.

Preferably, the photosensitive dielectric layer, also the outermost layer, of the buildup laminates has at least one slot which exposes an internal trace to provide embedment of electronic components.

Preferably, the photosensitive dielectric layer, also the outermost layer, of the buildup materials is a contact end. The contact end is arranged in a matrix configuration or a circular configuration to provide electrical connection between a plurality of wafer testing probes.

Preferably, the Multi-Core base includes at least one signal pattern layer, one power pattern supply layer, and one grounded pattern layer and the signal pattern layer, power pattern supply layer, and grounded pattern layer are electrically connected to the first, second circuit layer.

Preferably, the Multi-core base substrate is a single-sided Multi-core base substrate or a double side Multi-core base substrate.

Preferably, the Multi-Core base substrate is a ceramic substrate, an organic substrate, a glass substrate, or an aluminum substrate.

As describe above, vias of a fine pitch interposer structure have miniaturized diameters such that the blind vias shows fine matrix arrangement for further improving fine pitch testing capability.

In order to further understand the instant disclosure, the following embodiments and illustrations are provided. However, the detailed description and drawings are merely illustrative of the disclosure, rather than limiting the scope being defined by the appended claims and equivalents thereof.

### BRIEF DESCRIPTION OF THE DRAWINGS

FIG. 1 is a side view of a conventional vertical wafer testing structure;

FIG. 2 is a cross-sectional view of the conventional interposer with multi-layer ceramic substrate;

FIG. 3 is a cross-sectional view of the conventional interposer with multi-layer organic substrate;

FIG. 4 is a schematic diagram of a fine pitch interposer structure illustrating an example of a contact end on a device under test (DUT) according to a first embodiment of the instant disclosure;

FIG. 4A is a cross-sectional view of the fine pitch interposer structure according to the first embodiment of the instant disclosure;

FIG. 4B is a schematic diagram of the fine pitch interposer structure illustrating another example of a contact end on a device under test (DUT) according to the first embodiment of the instant disclosure;

FIG. 5 is a cross-sectional view of the fine pitch interposer structure according to a second embodiment of the instant disclosure;

FIG. 6 is a cross-sectional view of the fine pitch interposer structure according to a third embodiment of the instant disclosure;

FIG. 7 is a top view of the fine pitch interposer structure according to a third embodiment of the instant disclosure;

FIG. 8A to 8E are cross-sectional views illustrating a single-sided buildup laminate of the fine pitch interposer structure;

FIG. 9A to 9E are cross-sectional views illustrating a double-sided buildup laminate of the fine pitch interposer structure;

FIG. 10A is a cross-sectional view illustrating a double-sided Multi-Core base substrate as the Multi-Core base substrate of the fine pitch interposer structure;

FIG. 10B is a cross-sectional view illustrating the Multi-Core base substrate having a multi-layer laminate as the Multi-Core base substrate of the fine pitch interposer structure;

FIG. 10C is a cross-sectional view illustrating the Multi-Core base substrate having another multi-layer laminate as the Multi-Core base substrate of the fine pitch interposer structure; and

FIG. 10D is a cross-sectional view illustrating the Multi-Core base substrate having a plurality of multi-layer laminates as the Multi-Core base substrate of the fine pitch interposer structure.

### DETAILED DESCRIPTION OF THE PREFERRED EMBODIMENTS

The aforementioned illustrations and detailed descriptions are exemplarities for the purpose of further explaining the scope of the instant disclosure. Other objectives and advantages related to the instant disclosure will be illustrated in the subsequent descriptions and appended drawings.

### First Embodiment

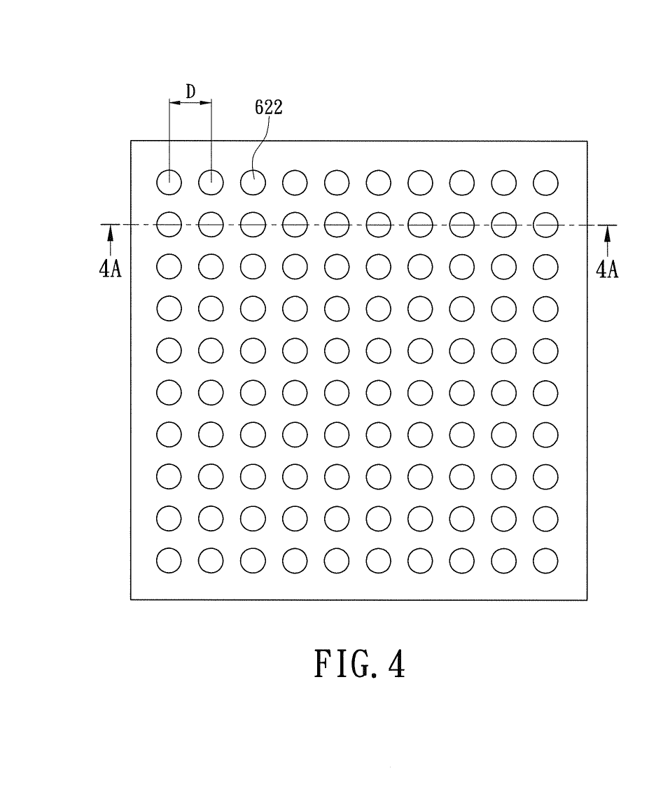

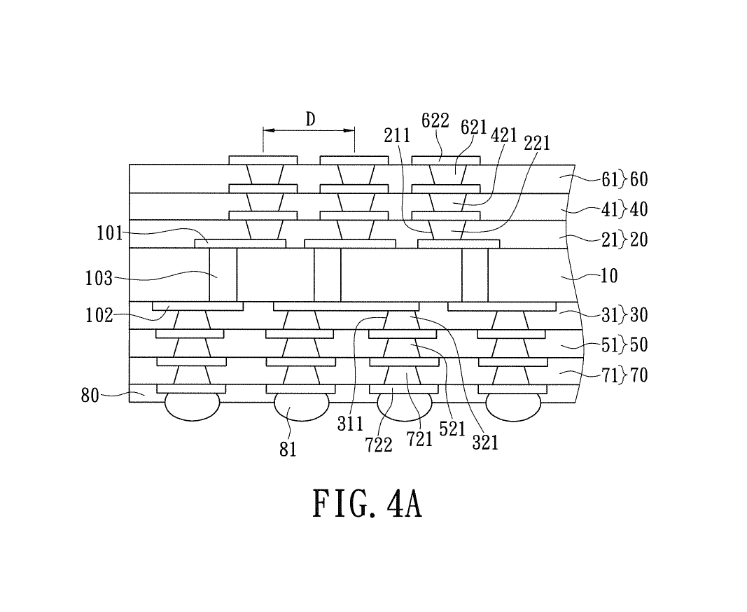

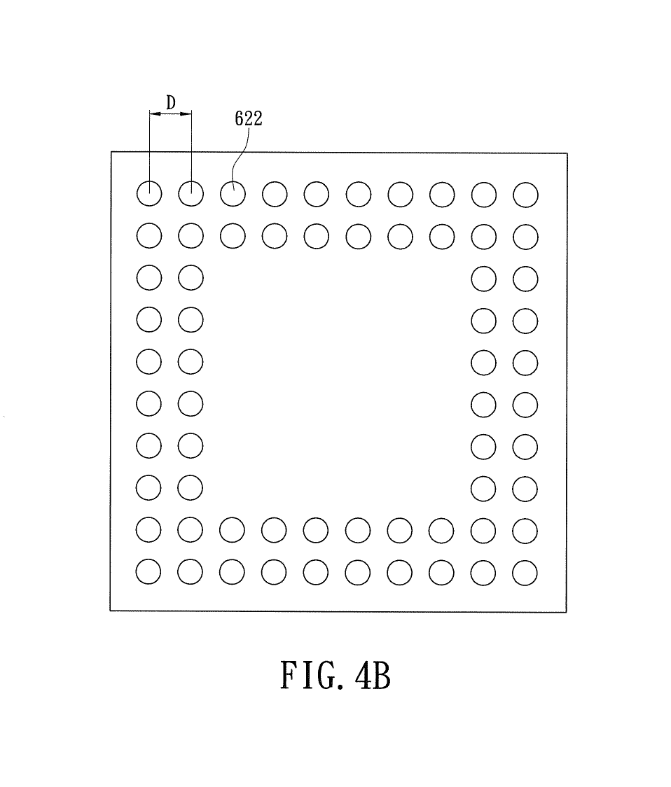

Refer to FIGS. 4 and 4A as the schematic diagram of the instant disclosure illustrating a fine pitch interposer structure. The interposer structure includes a Multi-Core base substrate 10 and a plurality of buildup laminates 20, 30, 40, 50, 60, 70 which are individually disposed on the opposing surfaces of the Multi-Core base substrate 10.

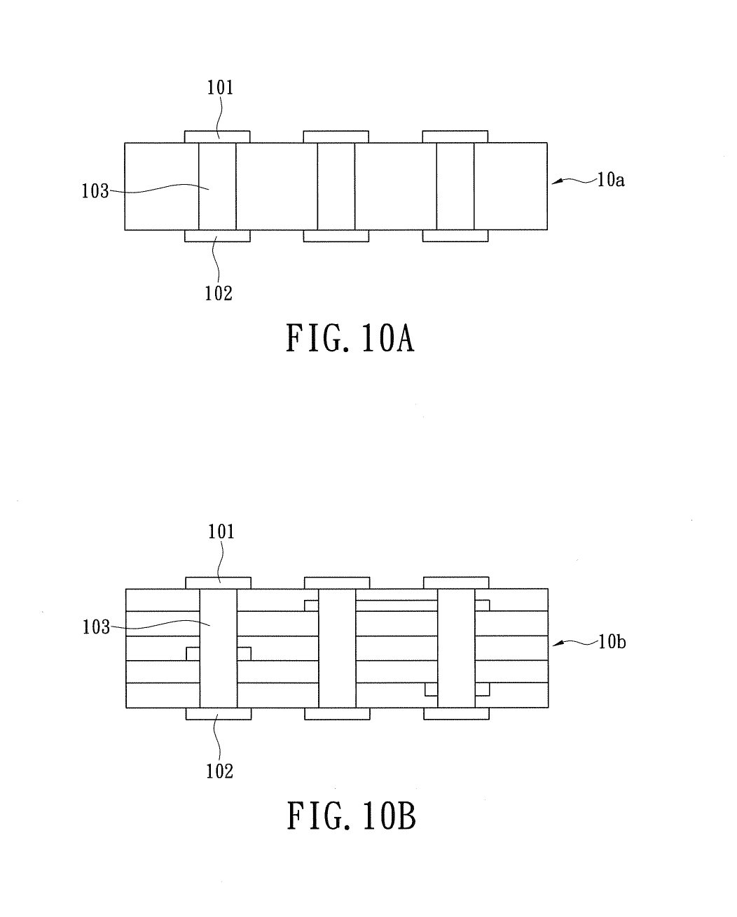

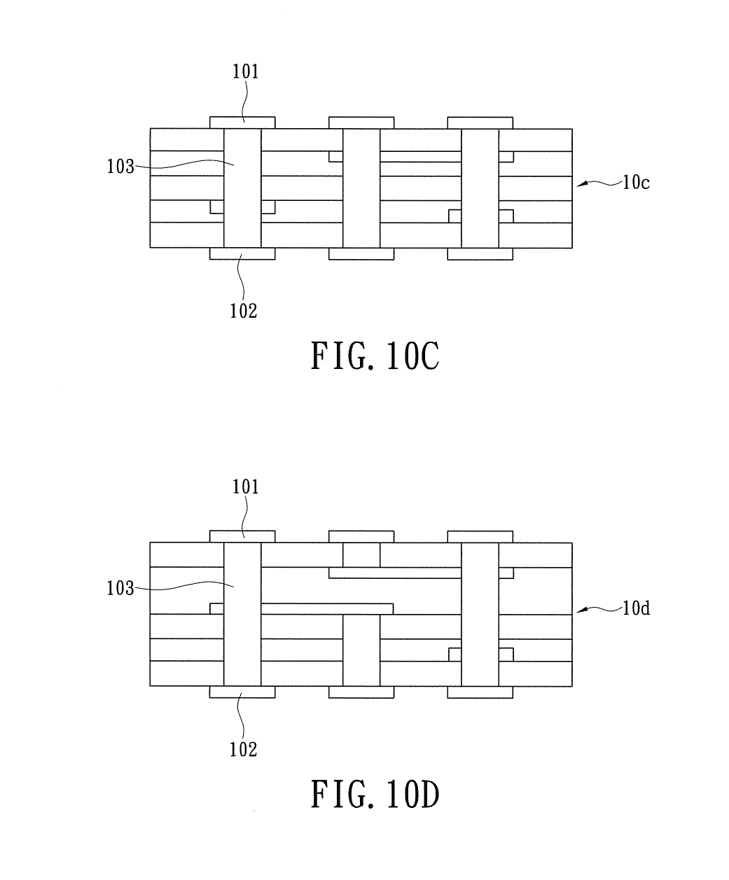

In the instant embodiment, the Multi-Core base substrate 10 is a double-sided Multi-Core base substrate as illustrated in FIG. 10A but is not limited thereto. As illustrated in FIGS. 10 A to 10 D, the Multi-Core base substrate can be a double-sided substrate as in FIG. 10A, a multi-layer laminate Multi-Core base substrate as in FIG. 10B, another type of multi-layer laminate Multi-Core base substrate as in FIG. 10C, or a plurality of multi-layer laminate Multi-Core base substrates as in FIG. 10D while a first circuit layer 101 and a second circuit layer 102 are disposed on the opposing surfaces of the substrate 10. The second circuit layer 102 is electrically connected to the first circuit layer 101 through a plating through hole 103.

As illustrated in FIG. 4A, the first buildup laminate 20 is formed on a surface of the Multi-Core base substrate 10. The first buildup laminate 20 includes a first photosensitive dielectric layer 21 and a plurality of first blind vias 221. The plurality of first blind vias 221 is arranged in a plurality of first via 211 formed on the first photosensitive dielectric layer 21. The first blind vias 221 are electrically connected to the first circuit layer 101 and are separately arranged with a pre-determined interval therebetween.

The second buildup laminate 30 is formed on a surface of the Multi-Core base substrate 10 opposing the first buildup laminate 20. The second buildup laminate 30 includes a second photosensitive dielectric layer 31, and a plurality of second blind vias 321. The plurality of second blind vias 321 is arranged in a plurality of second vias 311 formed on the second photosensitive dielectric layer 31, and is electrically connected to the second circuit layer 102.

Specifically, the instant embodiment uses a double-sided buildup laminate where the first, second buildup laminates 20, 30 are disposed on the opposing surfaces of the substrate 10. The quantity of the buildup laminates is not limited to the example provided therein. In the instant embodiment, a third, a fifth buildup laminate 40, 60 and a fourth, sixth buildup laminate 50, 70 are respectively disposed on the first, second buildup laminate 20, 30. The third buildup laminate 40 is formed with a plurality of third blind vias 421 superimposing the first blind vias 221 while the fifth buildup laminate 60 is formed with a plurality of fifth blind vias 621 superimposing the third blind vias 421. Similarly, the fourth buildup laminate 50 is formed with a plurality of fourth blind vias 521 superimposing the second blind vias 321 while the sixth buildup laminate 70 is formed with a plurality of sixth blind vias 721 superimposing the fourth blind vias 521. As a result, a stacked configuration is established which enhances circuit density during circuit routing.

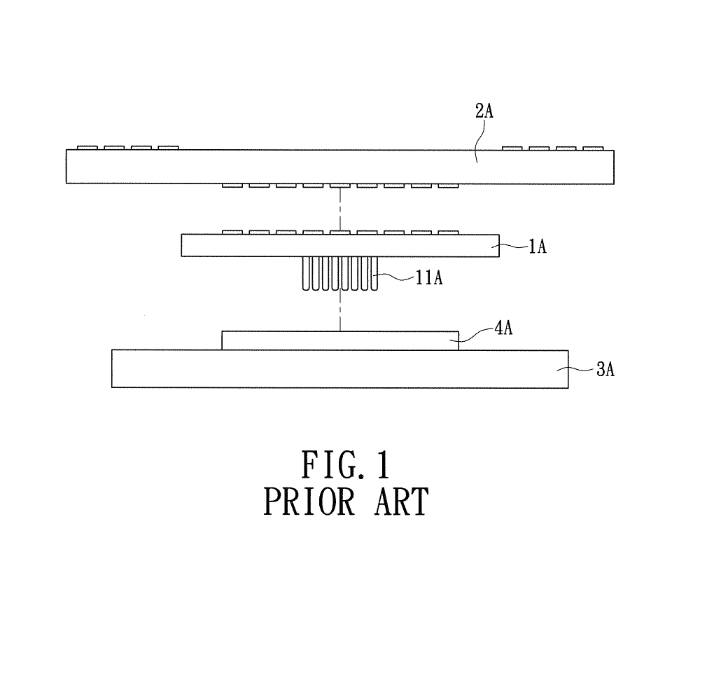

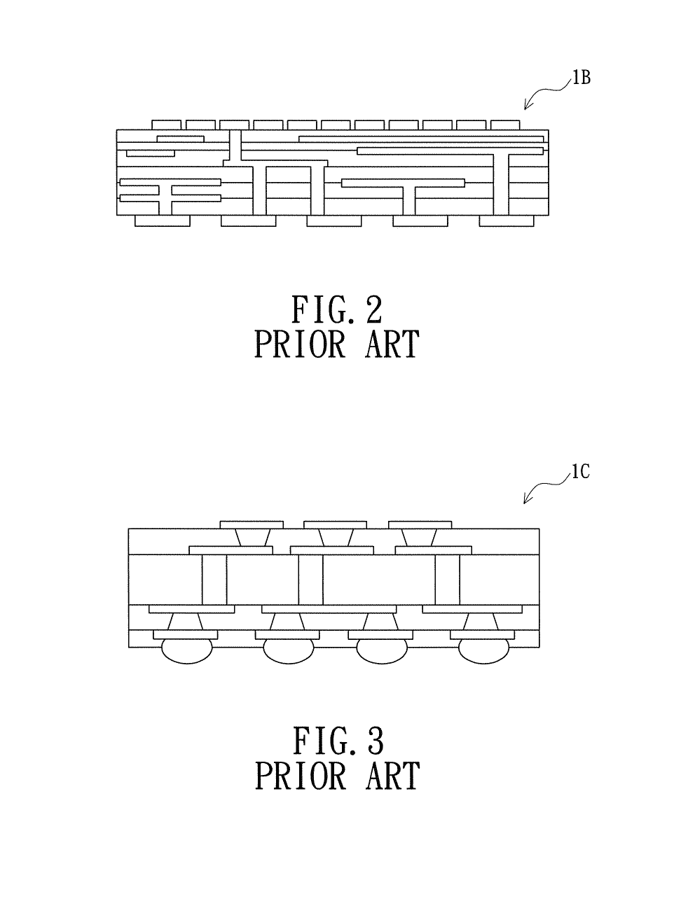

In the instant embodiment, the fifth buildup laminate 60 is the outermost end, or the contact end, of the fine pitch interposer structure. The fifth blind vias 621 are coupled with a plurality of contact pads 622 to provide electrical connection between a plurality of wafer test probe 11A (as FIG. 1.) and the central region of the contact pads 622. The contact pads 622 may have an array configuration (as FIG. 4) or a circular configuration (as FIG. 4B). The distance between two center points of two adjacent contact pads 622 is defined as a pitch D which is less than or equals to 140 microns. In practice, the pitch D depends on the actual wafer being tested. The testing capability of the fine pitch interposer relies on the pitch D.

The sixth buildup laminate 70 is the other outermost end, bump end, of the fine pitch interposer structure. The sixth blind vias 721 are coupled with a plurality of soldering pads 722 while a solder mask 80 is deposited over the soldering pads 722 and the sixth buildup laminate 70. Each of the soldering pads 722 is planted with a solder ball 81 to provide electrical connection with a Device Under Test (DUT) printed circuit board (PCB) 2A (as FIG. 1). The establishment of electrical connection is not limited to soldering.

### Second Embodiment

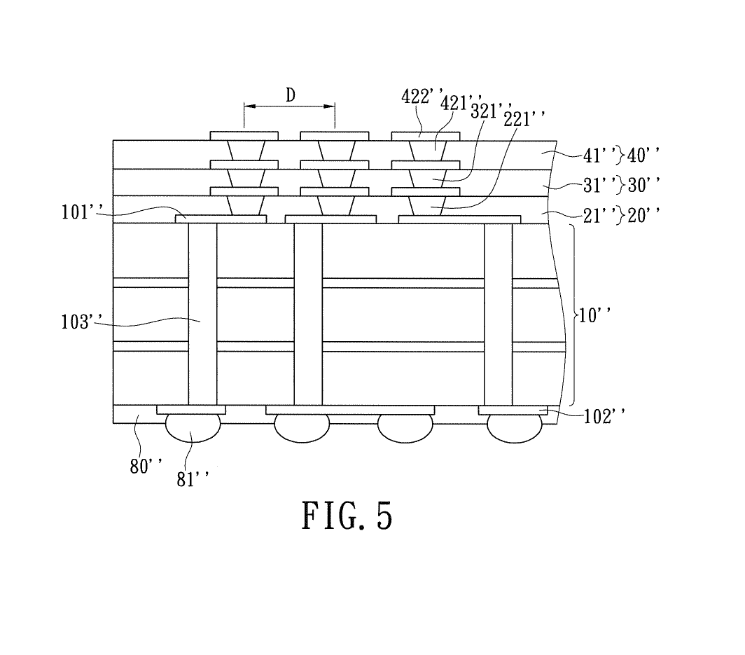

Refer to FIG. 5 as the second embodiment of the instant disclosure. The second embodiment differs from the previous embodiment in that the Multi-Core base substrate 10″ is a multi-layer Multi-Core base substrate where the overall buildup laminate structure is formed on a single side of the substrate 10″, and the quantity of the buildup laminates is not limited to examples provided herein. Specifically in the instant embodiment, a first, second, and third buildup laminate 20″ 30″ 40″ are successively disposed on the Multi-Core base substrate 10″. A plurality of second blind vias 321″ are superimposed on a plurality of first blind vias 221″ while a plurality of third blind vias 421″ are superimposed on the plurality of second blind vias 321″ to form the stacked configuration.

Furthermore, through the multi-layer Multi-Core base substrate structure, the Multi-Core base substrate 10″ may pre-design as desired with traces wider than the typical width on a signal pattern layer (not shown), a power supply pattern layer (not shown), and a grounded pattern layer (not shown) compared to default sizes. The signal pattern layer, power supply pattern layer, and grounded pattern layer are electrically connected to a first, second circuit layer 101″ 102″.

The third buildup laminate 40″ in the instant embodiment is the outermost layer and the contact end of the fine pitch interposer structure. The third blind vias 421″ has a plurality of contact pads 422″ which provides electrical connections between the plurality of wafer test probes 11A (as shown in FIG. 1) and the central region of the contact pads 422″.

The second circuit layer 102″ in the instant embodiment is the bump end of the fine pitch interposer structure. A solder mask 80″ is disposed on top of the second circuit layer 102″ while a plurality of solder balls 81″ is planted therein to provide electrical connection with the printed circuit board A2 (as FIG. 1), and the mentioned electrical connection with the PCB is not limited to soldering.

### Third Embodiment

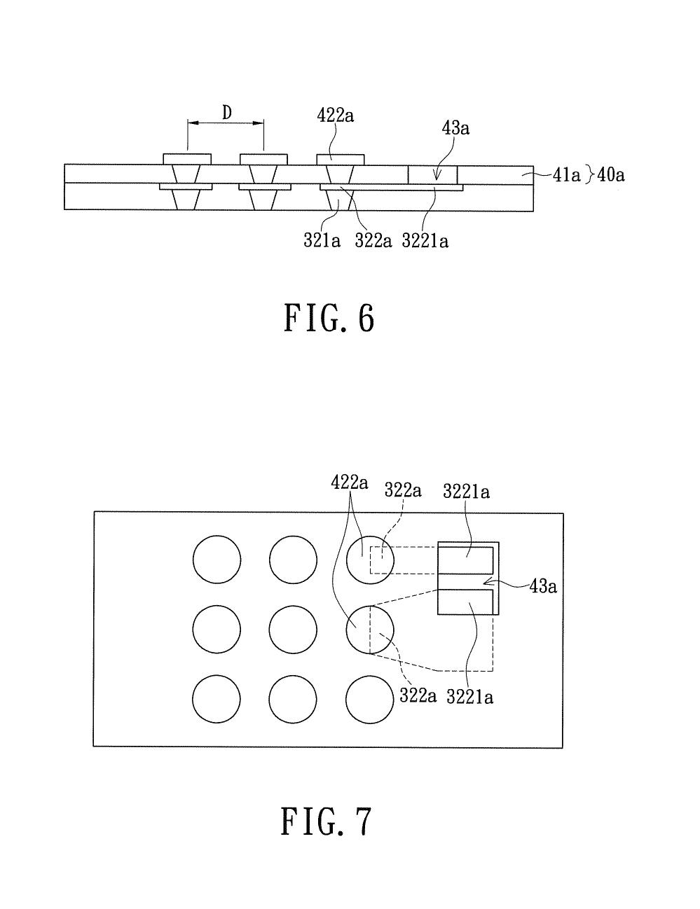

Refer to FIGS. 6 and 7 for illustrations of the third embodiment. The instant embodiment differs from the previous embodiments in that the photosensitive dielectric layer 41a which is disposed on the outermost buildup laminate 40a is formed with a slot 43a. A connection pad 322a is extended to form an internal trace layer 3221a which partially exposes through the slot 43a, thus allowing electrical components such as resistors, capacitors, and inductors to embed therein. The slot 43a is arranged proximate to the DUT end of the internal trace layer 3221a, thus shortening the distance between the trace and electric components and enhancing electrical connectivity. By embedding various types of electrical components, different functions such as coordination of radio frequency, filtering, and power integration are achieved.

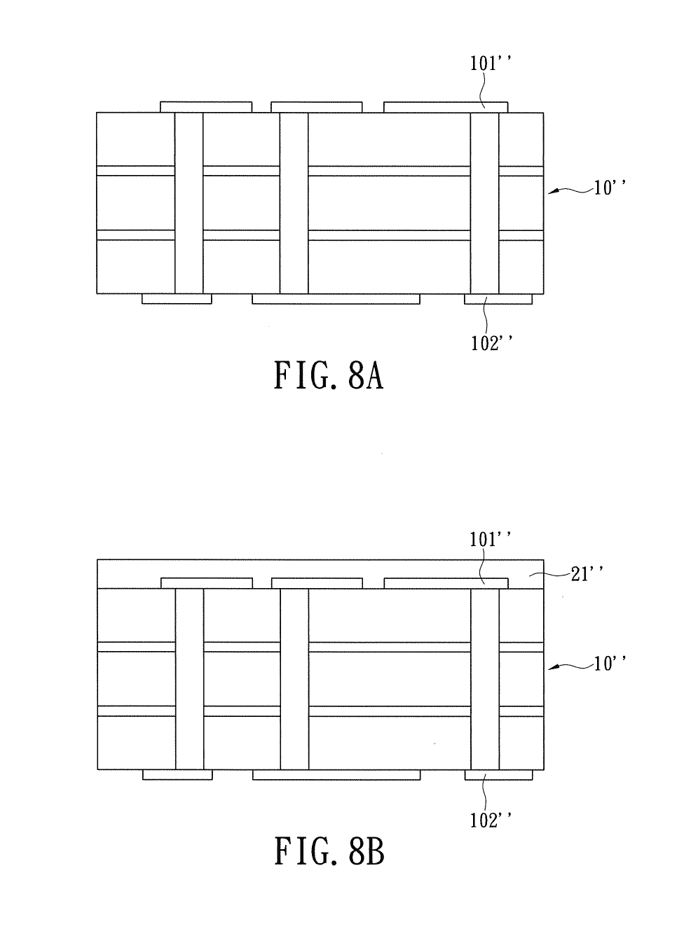

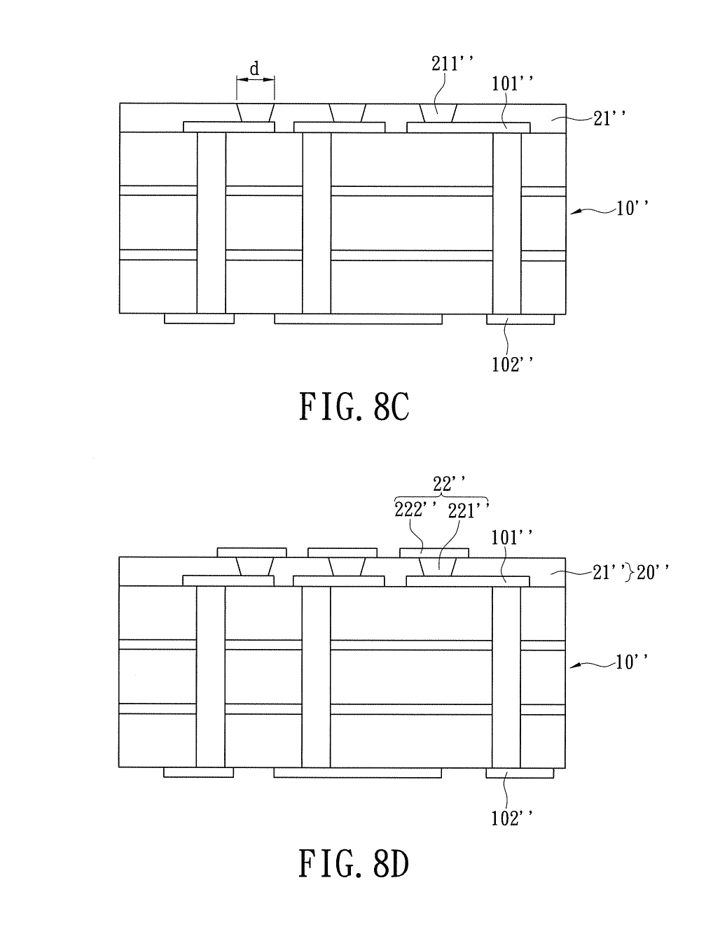

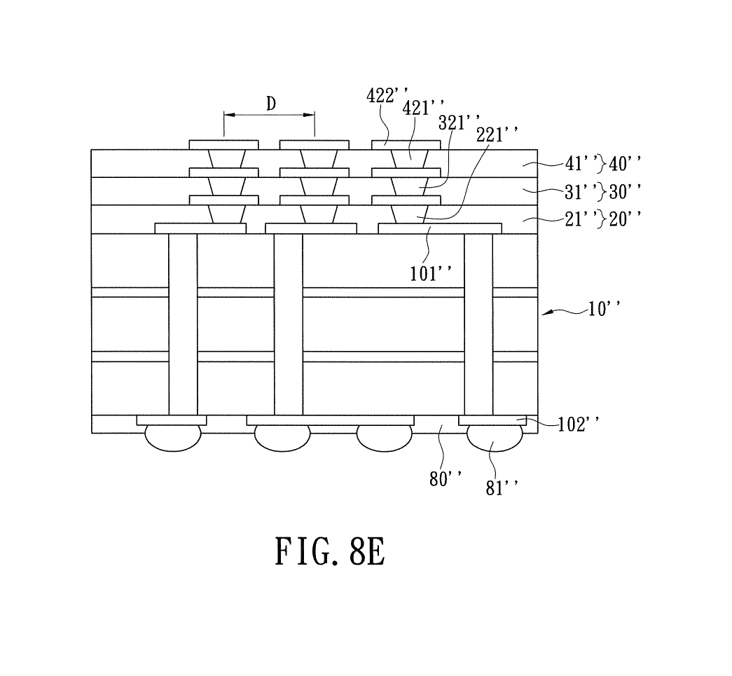

Moreover, refers to FIGS. 8A to 8E as the schematic diagrams illustrating the overall fabrication process of the single-sided buildup laminate structure. The Multi-Core base substrate 10″ is a multi-layer Multi-Core base substrate in which a first circuit layer 101″ and a second circuit layer 102″ are formed respectively on opposing surfaces thereof. Then, a first photosensitive dielectric layer 21″ is deposited on the core substrate 10″ and over the first circuit layer 101″. A plurality of first vias 211″ is developed on the first photosensitive dielectric layer 21″ via photolithography to partially expose the first circuit layer 101″. The diameter d of each first via 211″ is less than 50 microns. The first photosensitive dielectric layer 21″ is a highly photosensitive dielectric material which under exposure to light develops a first via 211″ having diameter d of 62.5 microns and below. In other words, the diameter d of the first vias 211″ is reduced through exposure in the instant disclosure, and the diameter d can be adjusted based on the film thickness of the photoresist. In practice, ultimately depending on the exposure capability of the equipment. The exposure process is generally more reliable than the laser ablation, which leaves post-processing epoxy residue behind, facilitates the passing of the short-circuit testing. Laser drilling is no longer necessary to form the first vias 211″ which leads to over drilling of the vias 211″. Successively, the first vias 211″ are copper 22″ electroplated to form a plurality of first blind vias 221″. Each of the first blind vias 221″ is coupled to a plurality of first connection pads 222″ defined as a first buildup laminate 20″ in the instant embodiment. As illustrated in FIG. 8E, a second buildup laminate 30″ is deposited on the first buildup laminate 20″ and a third buildup laminate 40″ is deposited on the second buildup laminate 30″ to form a single-sided buildup laminate structure of the instant disclosure.

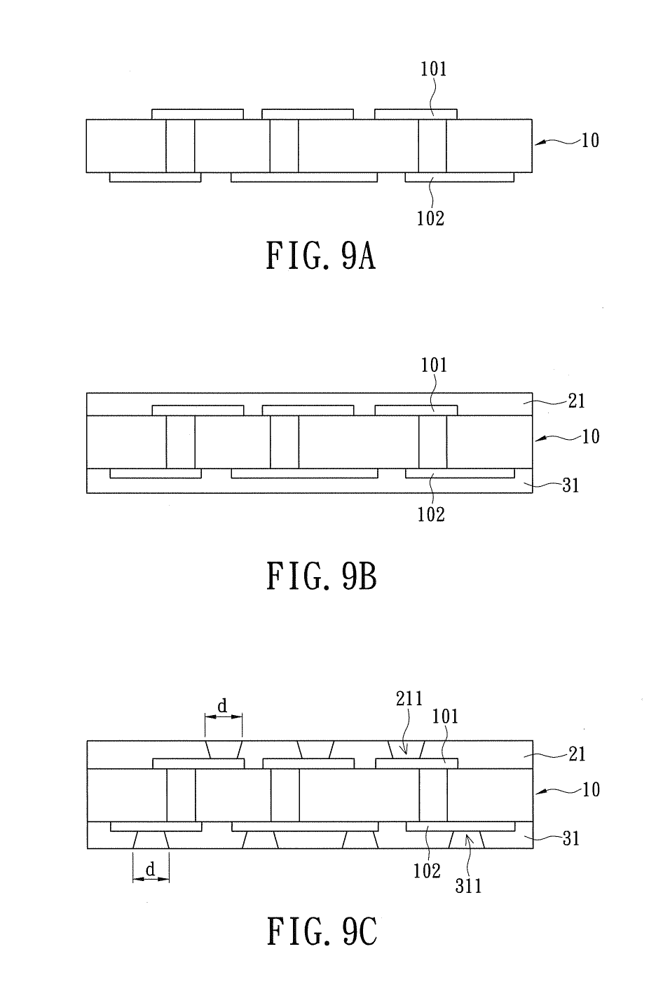

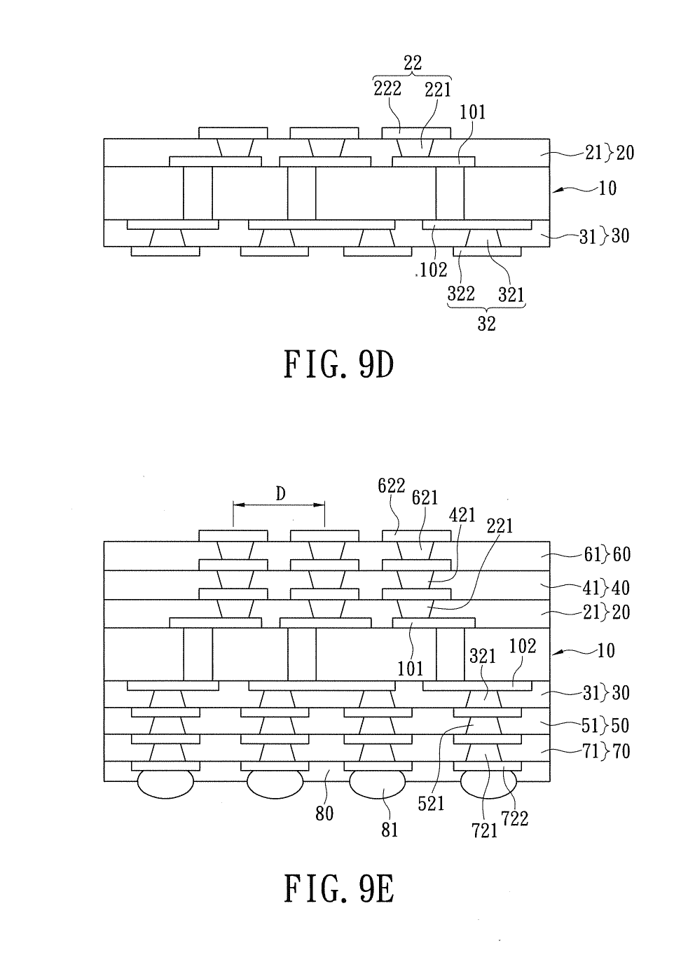

Refers to FIG. 9A to 9E as illustrations of the fabrication process of a double-sided buildup laminate structure. The Multi-Core base substrate 10 is a single-sided Multi-Core base substrate having opposing surfaces respectively formed with a first circuit layer 101 and a second circuit layer 102. Moreover, a first photosensitive dielectric layer 21 and a second photosensitive dielectric layer 31 are respectively deposited on the surfaces of the first, second circuit layer 101, 102. Through photolithography, the plurality of first vias 211 and second vias 311 are respectively formed on the first, second dielectric layer 21, 31 to respectively and partially expose the first, second circuit layer 101, 102. The diameters d of the first, second vias 211, 311 are less than 62.5 microns. The first, second vias 211, 311 are then copper 22, 32 electroplated to respectively formed a plurality of first, second blind vias 221, 321 thereon. Each first blind via 221 and each second blind via 321 are respectively coupled to a first connection pad 222 and a second connection pad 322 to complete the first, second buildup laminate 20, 30 structure. As illustrated in FIG. 9E, a third, a fifth buildup laminate 40, 60 and a fourth, a sixth buildup laminate 50, 70 are respectively disposed on the first, second buildup laminate 20, 30 to complete the double-sided buildup laminate structure of the instant disclosure.

In summary, the instant disclosure includes the miniaturized diameter of the vias with the application of photoresists as the dielectric layers and the photolithography while removing the machine processing and Desmear processing to resolve the problem of diameter formed larger than desired. Since the finer the diameter, the finer the pitch which in turn facilitate finer pitch circuit layout, enhance the density of circuits in multi-layer circuitry, and facilitate Multi-DUT layout design. Furthermore, via photoresists and photolithography, a slot is formed proximate to the DUT end such that electrical components are embedded on the internal traces, thus, improving upon the common layout design and enhancing power integrity.

The figures and descriptions supra set forth illustrated the preferred embodiments of the instant disclosure; however, the characteristics of the instant disclosure are by no means restricted thereto. All changes, alternations, combinations or modifications conveniently considered by those skilled in the art are deemed to be encompassed within the scope of the instant disclosure delineated by the following claims.

What is claimed is:

1. A fine pitch interposer structure, comprising:
a Multi-Core base substrate having opposing surfaces, each of the opposing surfaces having a first circuit layer and a second circuit layer respectively, the first and second circuit layers electrically connected to each other; and
a plurality of buildup laminates stacked on the surface of the Multi-Core base substrate in succession, each buildup laminate including: a photosensitive dielectric layer having a plurality of vias; and a plurality of blind vias arranged within the plurality of vias respectively by predetermined intervals and electrically connected to the first circuit layer; wherein the blind vias of the at least one buildup laminate superimpose the blind vias of the other buildup laminate.

2. The fine pitch interposer structure as recited in claim 1, wherein the diameter of each of the vias is no more than 62.5 microns.

3. The fine pitch interposer structure as recited in claim 1, wherein the blind vias are arranged in an array and the distance measured from the center of one blind via to the center of the other adjacent blind via is no more than 140 microns.

4. The fine pitch interposer structure as recited in claim 1, wherein the outermost photosensitive dielectric layer has at least one slot arranged thereon, the slot exposes an internal trace layer to provide embedment of electronic components.

5. The fine pitch interposer structure as recited in claim 4, wherein the outermost, photosensitive dielectric layer, layer of the buildup laminates is a contact end formed with a plurality of contact pads electrically connected to a plurality of wafer testing probes and arranged in a circular configuration.

6. The fine pitch interposer structure as recited in claim 4, wherein the outermost, photosensitive dielectric layer, layer of the buildup laminates is a contact end formed with a plurality of contact pads electrically connected to a plurality of wafer testing probes and arranged in a matrix configuration.

7. The fine pitch interposer structure as recited in claim 1, wherein the Multi-Core base substrate includes at least one signal pattern layer, one power supply pattern layer, and one grounded pattern layer and the signal pattern layer, power supply pattern layer, and grounded pattern layer are electrically connected to the first and second circuit layer.

8. The fine pitch interposer structure as recited in claim 1, wherein the Multi-Core base substrate is a single-layer Multi-Core base substrate or a multi-layer Multi-Core base substrate.

9. The fine pitch interposer structure as recited in claim 1, wherein the Multi-Core base substrate is a ceramic substrate, an organic substrate, a glass substrate, or an aluminum substrate.
